(19) United States
(12) Patent Application Publication
(10) Pub. No.: US 2023/0349068 A1
(43) Pub. Date: Nov. 2, 2023

(54) METHODS OF DEPOSITING FILMS WITH THE SAME STOICHIOMETRIC FEATURES AS THE SOURCE MATERIAL

(71) Applicant: Board of Regents, The University of Texas System, Austin, TX (US)

(72) Inventors: Manuel Quevedo Lopez, Richardson, TX (US); Jesus Alfonso Caraveo Frescas, Richardson, TX (US); Martin Gregorio Reyes Banda, Richardson, TX (US); Leunam Fernandez Izquierdo, Dallas, TX (US); Iker Rodrigo Chavez-Urbiola, Dallas, TX (US); Xavier Mathew, Richardson, TX (US)

(21) Appl. No.: 18/042,362

(22) PCT Filed: Aug. 25, 2021
(86) PCT No.: PCT/US2021/047525

§ 371 Date: Feb. 21, 2023

Related U.S. Application Data
(60) Provisional application No. 63/070,625, filed on Aug. 26, 2020.

(51) Int. Cl. C30B 23/06; C30B 29/12; C30B 23/02; C30B 23/00; C30B 33/02

(52) U.S. Cl. CPC C30B 23/066; C30B 23/063; C30B 29/12; C30B 23/025; C30B 23/002; C30B 33/02

(57) ABSTRACT

Methods for depositing films using crystals or powders as a source material are provided. The films can have a thickness of at least 100 nanometers and can be inorganic (e.g., inorganic perovskite) films, and the source material can be the same composition and/or stoichiometry as the deposited film. The deposition process can be a single-step thermal process using a close space sublimation (CSS) process.

### CROSS REFERENCE TO RELATED APPLICATION

This application claims the benefit of U.S. Provisional Application Ser. No. 63/070,625, filed Aug. 26, 2020, the disclosure of which is hereby incorporated by reference in its entirety, including any figures, tables, and drawings.

### BACKGROUND

Cesium lead bromide (CsPbBr₃) has a direct band gap in the range of 2.16 electron Volts (eV) to 2.25 eV for bulk single crystals and about 2.3 eV for thin films. In addition to high stability, CsPbBr₃ possesses interesting electronic and optoelectronic properties such as high attenuation above the band gap, good photo response, large electron and hole mobility, long lifetimes, low excitation binding energy, halogen self-passivation, defect tolerance, and luminosity. Device quality single crystals have been prepared using high temperature processes, solution-based methods, and inverse temperature crystallization.

The carrier concentration of solution grown crystals varies in the range 4.55×10⁷ cm⁻³ to 1.4×10⁸ cm⁻³ for holes and about 1.1×10⁹ cm⁻³ for electrons, making the crystals nearly intrinsic with resistivities in the range 1-3 giga-Ohms per centimeter (GΩ-cm). As a reference, Bridgman grown crystals show resistivities as high as about 340 GΩ-cm and mobility-lifetime (μτ) product for electrons and holes in the range 1.7 10⁻³ to 4.5×10⁻⁴ square centimeters per Volt (cm²/V) and 1.3×10⁻³ to 9.5×10⁻⁴ cm²/V, respectively. These μτ values are better than that of CdZnTe (CZT) and CdTe. The electron μτ product of CZT and CdTe are in the lower range of the corresponding values for CsPbBr₃ while the hole μτ product is only 0.1% that of CsPbBr₃.

### BRIEF SUMMARY

Embodiments of the subject invention provide novel and advantageous methods for depositing films using crystals or powders as a source material. The films can have a thickness of at least 100 nanometers (nm) (e.g., at least 1 micrometer (μm) or at least 5 μm) and can be thick films or thin films (e.g., thickness of 50 μm or less). The films can be inorganic (e.g., inorganic perovskite) films, and the source material can be the same composition and/or stoichiometry as the deposited film. The deposition process can be a single-step thermal process using a close space sublimation (CSS) process. The source material and film material can be, for example, cesium lead bromide (CsPbBr₃), methylammonium (MA) lead bromide (MAPbBr₃), MA lead iodide (MAPbI₃), MA lead chloride (MAPbCl₃), cesium lead chloride (CsPbCl₃), or cesium lead iodide (CsPbI₃), though embodiments are not limited thereto. The films can be of, for example, mixed halides systems (e.g., CsPb(BrₓCl₁₋ₓ)₃) to tune optical and electrical properties of the films.

In an embodiment, a method for depositing a film on a substrate can comprise: providing a source material on a first heater, the source material comprising single crystals; providing the substrate on a second heater, the substrate being disposed a first distance from the source material, the first distance being less than 10 millimeters (mm); and performing a CSS process to deposit the film of the source material on the substrate by simultaneously heating the source material with the first heater to a first temperature and heating the substrate with the second heater to a second temperature, wherein the film has the same stoichiometry as the source material. The first distance can be, for example, no more than 3 mm (e.g., in a range of 2 mm to 3 mm). The source material can be inorganic. The source material can be a perovskite material and the film can be a perovskite film. The source material can be, for example, CsPbBr₃ and the film can be a CsPbBr₃ film. The film can have a thickness in a range of from 100 nm to 100 μm (e.g., in a range of from 1 μm to 50 μm, and/or at least 5 μm). The source material can comprise a powder of the single crystals ground up. The source material can be provided on the first heater in a container (e.g., a crucible). The container can be in direct physical contact with the first heater and/or the substrate can be in direct physical contact with the second heater. The substrate can be, for example, glass. The first temperature can be different than the second temperature. The first temperature can be higher than (e.g., at least twice the value of) the second temperature. The first temperature and the second temperature can be independently controlled. The first temperature and the second temperature can be controlled by a first thermocouple and a second thermocouple, respectively. The method can further comprise, after performing the CSS process: allowing the substrate to cool to room temperature; and performing a post-deposition annealing on the film by heating it to a third temperature (e.g., at least 450° C.) for a predetermined period of time (e.g., at least 1 hour). The film can have the same composition as the source material. A grain size of the film can be the same (or about the same) as a thickness of the film. The source material can be prepared using an antisolvent vapor crystallization (AVC) method (as disclosed herein).

In another embodiment, a film can be deposited using the methods disclosed herein. The film can be, for example, a perovskite film and/or an inorganic film. The film can be, for example, a CsPbBr₃ film.

### BRIEF DESCRIPTION OF DRAWINGS

FIG. 1(a) shows a schematic view of an antisolvent vapor crystallization (AVC) approach for growth of crystals (e.g., CsPbBr₃ crystals). Though the figure refers to CsPbBr₃ crystals and a temperature of 25° C., these are for exemplary purposes only. Other material crystals can be grown, and the temperature can be different (e.g., a similar room temperature).

FIG. 1(b) shows a schematic view of a close space sublimation (CSS) process, according to an embodiment of the subject invention, using crystals as the source material to fabricate a thin film of the same stoichiometry and composition as the source material. Though the figure refers to CsPbBr₃ source material, CsPbBr₃ thin film deposition, and temperatures of 250° C. and 500° C., these are for exemplary purposes only. Other source material crystals can be used, and the thin film deposited will be the same composition as the source material; also, different temperature may be used.

FIG. 1(c) shows a schematic view of a diode having a thin film (labeled in FIG. 1(c) as CsPbBr₃) produced by a CSS process according to an embodiment of the subject invention. The cathode (+) and anode (−) are labeled, as are the electrical contacts (indium tin oxide (ITO) and gold). A semiconductor material can be used (e.g., Ga₂O₃, such as n-type Ga₂O₃). Though the figure refers to the diode being a CsPbBr₃ diode, the thin film being CsPbBr₃, the electrical contacts being ITO and gold, and the semiconductor being Ga₂O₃, these are for exemplary purposes only. Other materials can be used.

FIG. 2(a) shows X-ray diffraction (XRD) patterns of a CsPbBr₃ film produced by a CSS process according to an embodiment of the subject invention, as well as CsPbBr₃ source crystals produced by an AVC approach. The reference XRD pattern included is for inorganic crystal structure database (ICSD) #97851.

FIG. 2(b) shows the X-ray photoelectron spectroscopy (XPS) spectrum of cesium (Cs) 3d.

FIG. 2(c) shows the XPS spectrum of lead (Pb) 4f FIG. 2(d) shows the XPS spectrum of bromine (Br) 3d.

FIG. 2(e) shows a top-view scanning electron microscope (SEM) image of an as-deposited CsPbBr₃ thin film, deposited by a CSS process according to an embodiment of the subject invention. The scale bar of FIG. 2(g), which is 2 μm, applies for this figure as well.

FIG. 2(f) shows a cross-sectional view SEM image of the as-deposited CsPbBr₃ thin film shown in FIG. 2(e). The scale bar of FIG. 2(g), which is 2 μm, applies for this figure as well.

FIG. 2(g) shows a cross-sectional view SEM image of the CsPbBr₃ thin film from FIG. 2(f), after polishing and annealing at 450° C. for 30 minutes. The scale bar is 2 μm.

FIG. 3(a) shows a plot of absorbance (arbitrary units (a.u.)) versus wavelength (λ, in nanometers (nm)) for a CsPbBr₃ thin film, deposited by a CSS process according to an embodiment of the subject invention. The deconvoluted photoluminescence (PL) bands are shown as dashed lines.

FIG. 3(b) shows a Tauc plot (E_{g}=2.32 electron Volts (eV)).

FIG. 3(c) shows a PL plot of single crystal CsPbBr₃ used as the precursor or source material in the CSS process for the thin film examined in FIG. 3(a).

FIG. 3(d) shows a plot of PL intensity (area) versus incident laser power (in megawatts (mW)), for the 526-nm and 546-nm bands. The PL spectra recorded at each incident laser power are shown in FIG. 17.

FIG. 3(e) shows a plot of PL intensity (in a.u.) versus time (in nanoseconds (ns)), giving the time-resolved photoluminescence (TRPL) of the film examined in FIG. 3(a). The TRPL shows carriers with two distinct lifetimes (τ₁=1.37 ns; and τ₂=4.28 ns). The equation for the best fit can be expressed as y(t)=A+B1e^{-t}/^{τ}^{₁}+B2e^{-t}/^{τ}^{₂}, where A=0.748, B1=2400, and B2=1520.

FIG. 4(a) shows a plot of current density (in Amps per square millimeter (A/mm²) versus voltage (in Volts (V)) for the Ga₂O₃/CsPbBr₃ thin film diode shown in FIG. 1(c). The inset plot of FIG. 4(a) shows the complete depletion of the device with a CsPbBr₃ film having a thickness of about 8 μm, at low reverse bias. The inset schematic is of the same device as shown in FIG. 1(c).

FIG. 4(b) shows a plot of responsivity (in Amps per Watt (A/W)) versus wavelength (in nm) for the Ga₂O₃/CsPbBr₃ thin film diode shown in FIG. 1(c), measured at −4 V applied bias.

FIG. 4(c) shows a plot of photoresponse (in V) versus time (in milliseconds (ms)) for the Ga₂O₃/CsPbBr₃ thin film diode shown in FIG. 1(c), under different applied biases. The lowest photoresponse in each grouping is for an applied bias of −1 V; the second-lowest photoresponse in each grouping is for an applied bias of −2 V; the third-lowest photoresponse in each grouping is for an applied bias of −3 V; and the highest photoresponse in each grouping is for an applied bias of −4 V.

FIG. 4(d) shows a plot of photoresponse (in a.u.) versus wavelength (in nm) for the Ga₂O₃/CsPbBr₃ thin film diode shown in FIG. 1(c), showing the rise/decay time estimation. The applied bias is −4 V.

FIG. 5(a) shows a plot of counts versus channel for alpha particle response of the Ga₂O₃/CsPbBr₃ thin film diode shown in FIG. 1(c), when exposed to a source of polonium-210 (²¹⁰Po). Data was collected for 180 minutes with a shaping time constant of 3 microseconds (μs). The inset shows counts above lower limit of detection (LLD) for alpha particles (the (black) line that rises over time) and noise (the (green) line that stays flat over time), recorded every 15 minutes; the y-axis for the inset is counts (×10⁴) and the x-axis for the inset is time (in minutes).

FIG. 5(b) shows a plot of counts versus channel for the Ga₂O₃/CsPbBr₃ thin film diode shown in FIG. 1(c) (the (green) lines that are mostly in the 180-350 channel area, with an LLD of 248 n/mm²/Hr) and the Ga₂O₃/CsPbBr₃ thin film diode after a PbCl₂ treatment (the (blue) lines that are mostly in the 220-520 channel area, with an LLD of 136 n/mm²/Hr). This shows the normalized neutron response of these diodes.

FIG. 5(c) shows a plot of counts versus channel for alpha particle response of a silicon diode. The LLD is 355 n/mm²/Hr. The Ga₂O₃/CsPbBr₃ thin film diode after a PbCl₂ treatment had 71.4% of the efficiency of the silicon diode.

FIG. 6(a) shows XRD patterns of CsPbBr₃ films produced by a CSS process according to an embodiment of the subject invention. XRD patterns for films with thicknesses of 15 μm (upper pattern), 9 μm (middle pattern), and 5 μm (lower pattern) are shown.

FIG. 6(b) shows XRD patterns for a CsPbBr₃ thick film at a grazing angle of 2.0 degrees (upper pattern) and 0.5 degrees (lower pattern).

FIG. 7(a) shows an XRD pattern of Cs₄PbBr₆ (ICSD #25124).

FIG. 7(b) shows an XRD pattern of CsPb₂Br₅ (see also [1] and [51]).

FIG. 8 shows a schematic view of precursor powder preparation from crystals. Though the figure refers to CsPbBr₃ crystals and CsPbBr₃ powder, these are for exemplary purposes only. Other materials can be used. FIG. 8 also shows a plot of temperature (in ° C.) versus time (in seconds (s)) for the deposition of a CsPbBr₃ thin film from CsPbBr₃ powder. The upper curve is for the crucible, and the lower curve is for the substrate. At time=2000 s, the heaters were switched off and the reactor was left to cool until the temperature reached below 50° C. The thickness of the film after the deposition time of 1800 s was 5 μm.

FIG. 9(a) shows an image of a glass substrate on which a CsPbBr₃ thin film was deposited.

FIG. 9(b) shows an image of a CsPbBr₃ thin film deposited using a CSS process, according to an embodiment of the subject invention.

FIG. 10 shows a schematic view of an AVC method for preparation of crystals (e.g., CsPbBr₃ crystals). Though the figure refers to certain materials and solvents, these are for exemplary purposes only and should not be construed as limiting.

FIG. 11(a) shows an XPS plot of CsPbBr₃ showing the carbon (C) is region of crystals. The lower (red) curve is for the C Is, and the higher (black) curve is for the CsPbBr₃ film.

FIG. 11(b) shows an XPS plot of CsPbBr₃ showing the oxygen (O) is region of crystals. The lower (red) curve is for the O 1s, and the higher (black) curve is for the CsPbBr₃ film.

FIG. 12(a) shows an XPS plot of CsPbBr₃ recorded in the Pb 4f region. The (black) curve that is slightly more left is for the fresh crystal powder, and the (red) curve that is slightly more to the right is for the residue left in the crucible after the CSS process.

FIG. 12(b) shows an XPS plot of CsPbBr₃ recorded in the Br 3d region. The (black) curve that is slightly more left is for the fresh crystal powder, and the (red) curve that is slightly more to the right is for the residue left in the crucible after the CSS process.

FIG. 12(c) shows an XPS plot of CsPbBr₃ recorded in the Cs 3d region. The (black) curve that is slightly higher at binding energy of 732 eV is for the fresh crystal powder, and the (red) curve that is slightly lower at binding energy of 732 eV is for the residue left in the crucible after the CSS process.

FIG. 12(d) shows an XPS plot of CsPbBr₃ recorded in the C is region. The (black) curve that is lower at binding energy of 284.8 eV is for the fresh crystal powder, and the (red) curve that is higher at binding energy of 284.8 eV is for the residue left in the crucible after the CSS process.

FIG. 12(e) shows an XPS plot of CsPbBr₃ recorded in the O 1s region. The (black) curve that is lower at binding energy of 532.48 eV is for the fresh crystal powder, and the (red) curve that is higher at binding energy of 532.48 eV is for the residue left in the crucible after the CSS process.

FIG. 13 shows a plot of intensity (a.u.) versus Raman shift (1/centimeters (cm⁻¹)) showing the deconvoluted Raman spectrum of a CsPbBr₃ thin film produced by a CSS process according to an embodiment of the subject invention. The broad band at 151 cm⁻¹ can be due to either motion of Cs⁺ ions or fluorescence.

FIG. 14 shows an SEM cross-sectional image of a CsPbBr₃ thin film produced by a CSS process according to an embodiment of the subject invention. The cross-section reveals columnar growth extending from substrate to surface of the film having a thickness of 8 μm. The scale bar is 2 μm. The numbers (1-5) labeled on FIG. 14 indicate locations from where the energy dispersive X-ray spectroscopy (EDXS) data were collected (see Table 3).

FIG. 15(a) is an atomic force microscopy (AFM) image of a surface of an as-deposited CsPbBr₃ thin film produced by a CSS process according to an embodiment of the subject invention. The film had a thickness of 9 μm and a roughness of 272.8 nm.

FIG. 15(b) is an AFM image of a surface of an as-deposited CsPbBr₃ thin film produced by a CSS process according to an embodiment of the subject invention. The film had a thickness of 15 μm and a roughness of 571.8 nm.

FIG. 15(c) is an AFM image of a surface of a CsPbBr₃ thin film produced by a CSS process according to an embodiment of the subject invention, after polishing. The polished film had a thickness of 13.5 μm and a roughness of 49 nm. After polishing (from FIG. 15(b) to FIG. 15(c)), the roughness reduced from about 571 nm to about 49 nm.

FIG. 16 shows a schematic view of an experimental arrangement used for obtaining and recording PL spectra from thin films and crystals (e.g., CsPbBr₃ thin films and/or crystals). Though the figure shows CsPbBr₃ as the material for the film/crystals, aluminum as the material for the foil, and 405 nm for the laser, these are for exemplary purposes only and should not be construed as limiting. Other materials or lasers could be used. The diameter of the pin-hole can be, for example, about 400 μm. The foil can cover the entire film/crystal to mask the PL emerging from the edges. PL can be collected in the reflection mode as seen in FIG. 16.

FIG. 17 shows a plot of PL intensity (a.u.) versus wavelength (in nm) for a CsPbBr₃ thin film, deposited by a CSS process according to an embodiment of the subject invention, recorded at different incident laser powers (from 0.133 mW to 0.023 mW). The laser exposed area of the sample was limited to about 400 μm with the use of a pin-hole on an aluminum (Al) fil, and the PL was collected in the reflection mode from the same area (see also FIG. 16 for a schematic of the arrangement used).

FIG. 18(a) shows XRD patterns of a CsPbBr₃ thin film, deposited by a CSS process according to an embodiment of the subject invention, as well as the CsPbBr₃ thin film after a treatment with PbCl₂. The top shows a reference XRD, the middle is after the PbCl₂ treatment, and the bottom is before the PbCl₂ treatment.

FIG. 18(b) shows a top-view SEM image of the CsPbBr₃ after treatment with PbCl₂. The scale bar is 2 μm.

FIG. 18(c) shows a plot of current density (in A/mm²) versus voltage (in V) for the CsPbBr₃ thin film, before and after a treatment with PbCl₂. The (blue) curve that has higher current density at a voltage of 5 V is for the CsPbBr₃ thin film before treatment with PbCl₂, and the (red) curve that has lower current density at a voltage of 5 V is for the CsPbBr₃ thin film after treatment with PbCl₂.

FIG. 18(d) shows a plot of signal (ΔV, in a.u.) versus time (in ms) giving the photo response of CsPbBr₃ and CsPbBr₃₋ₓClₓ (e.g., CsPbBr₃+PbCl₂) based devices. The (blue) curve that is higher is for CsPbBr₃, and the (black) curve that is lower is for CsPbBr₃ after treatment with PbCl₂.

FIG. 19 shows images of mixed halide thin film, deposited by a CSS process according to an embodiment of the subject invention. The images go from higher bromine concentration on the left to higher chlorine concentration on the right. Each film had a thickness of 5 μm and was deposited on a glass substrate using single crystals prepared from an AVC method as source material.

FIG. 20 shows images of CsPbCl₃ crystals prepared by an AVC method (left) and the resulting thin film on a glass substrate after the CSS process (right).

FIG. 21(a) shows a schematic view of a CSS setup/reactor that can be used for CSS processes, according to an embodiment of the subject invention. The container (e.g., a crucible) can be disposed on a bottom heater and contains the material to be sublimated. The substrate onto which the film is to be deposited can be positioned above the container (e.g., crucible). The substrate can be in direct physical contact with a top heater (in FIG. 21(a) there is a gap shown for clarity of the substrate, but in practice this gap can be eliminated such that the substrate is in direct physical contact with the top heater). The temperatures of the container (e.g., crucible) and the substrate can be independently controlled (e.g., using thermocouple sensors or similar temperature control devices).

FIG. 21(b) shows a plot of temperature (in ° C.) versus time (in s) showing temperature deposition values used to achieve a precursor film of PbBr₂ by CSS with a thickness of about 2.3 μm. The lines with the higher values are for the source (e.g., container/crucible), and the curve with the lower values is for the substrate.

FIG. 21(c) shows a plot of temperature (in ° C.) versus time (in s) showing temperature deposition values used to achieve a film of methylammonium (MA) bromide (MABr) by CSS with a thickness of about 3 μm. The curve with the higher values is for the source (e.g., container/crucible), and the curve with the lower values is for the substrate.

FIG. 21(d) shows a plot of temperature (in ° C.) versus time (in s) showing optimized temperature-time profile of the post-deposition processing protocol to obtain fully-converted MA lead bromide (MAPbBr₃). The curve with the higher values is for the source (e.g., container/crucible), and the curve with the lower values is for the substrate.

FIG. 22(a) shows an image of MAPbBr₃ deposited by a CSS process, according to an embodiments of the subject invention.

FIG. 22(b) shows an image of MA lead chloride (MAPbCl₃) deposited by a CSS process, according to an embodiments of the subject invention.

### DETAILED DESCRIPTION

Embodiments of the subject invention provide novel and advantageous methods for depositing films using crystals or powders as a source material. The films can have a thickness of at least 100 nanometers (nm) (e.g., at least 1 micrometer (μm) or at least 5 μm) and can be thick films or thin films (e.g., thickness of 50 μm or less). The films can be inorganic (e.g., inorganic perovskite) films, and the source material can be the same composition and/or stoichiometry as the deposited film. The deposition process can be a single-step thermal process using a close space sublimation (CSS) process. The source material and film material can be, for example, cesium lead bromide (CsPbBr₃), methylammonium (MA) lead bromide (MAPbBr₃), MA lead iodide (MAPbI₃), MA lead chloride (MAPbCl₃), cesium lead chloride (CsPbCl₃), or cesium lead iodide (CsPbI₃), though embodiments are not limited thereto. The films can be of, for example, mixed halides systems (e.g., CsPb(BrₓCl₁₋ₓ)₃) to tune optical and electrical properties of the films.

When the term “approximately” or “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05.

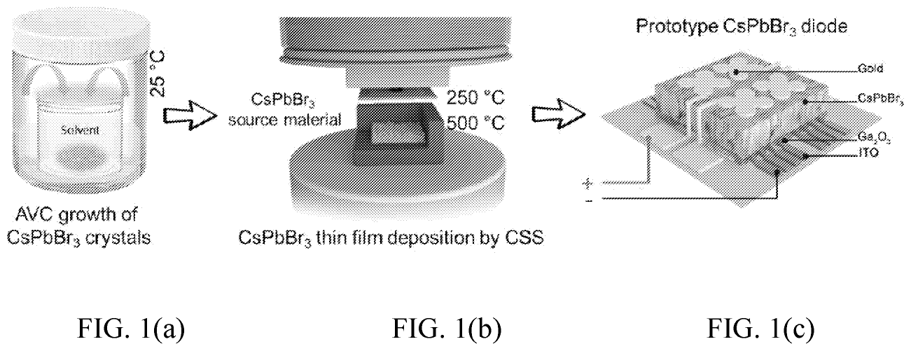

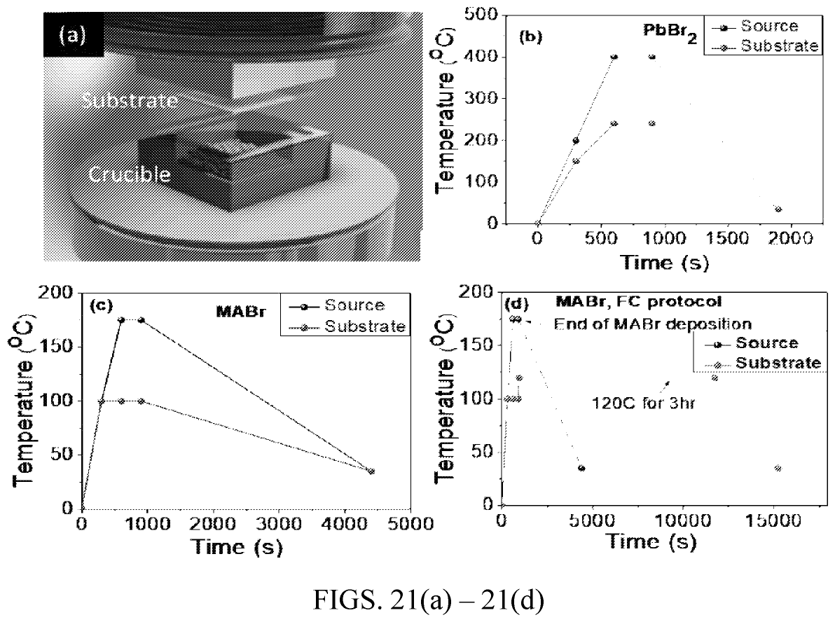

FIG. 1(b) shows a schematic view of a CSS process according to an embodiment of the subject invention. Though FIG. 1(b) refers to CsPbBr₃ source material, CsPbBr₃ thin film deposition, and temperatures of 250° C. and 500° C., these are for exemplary purposes only. In addition, FIG. 21(a) shows a schematic view of a CSS setup/reactor that can be used for CSS processes, according to an embodiment of the subject invention.

Referring to FIG. 1(b) and FIG. 21(a), a source material to be sublimated can be provided in a container, and the container (e.g., a crucible) can be disposed on a bottom heater (while containing the material to be sublimated). The substrate onto which the film is to be deposited can be positioned above the container. The substrate can be in direct physical contact with a top heater (in FIG. 21(a) there is a gap shown for clarity of the substrate, but in practice this gap can be eliminated such that the substrate is in direct physical contact with the top heater). The temperatures of the container and the substrate can be independently controlled (e.g., using thermocouple sensors or similar temperature control devices), and the temperature of the container can be kept higher than the temperature of the substrate. For example, the temperature of the container can be about twice the temperature of the substrate. The substrate can be any rigid material that can withstand the necessary temperatures of the CSS process. In many cases, the substrate can be an insulating material, such as glass, though embodiments are not limited thereto.

CSS is a capable of depositing high quality films. Because the separation between the source (i.e., the source material, such as the container containing the source material) and the substrate is in the range of 2 millimeters (mm) to 3 mm, the substrate and the depositing species are in near-thermal equilibrium, which results in films with less defects. No related art methods exist for depositing perovskite material films by CSS.

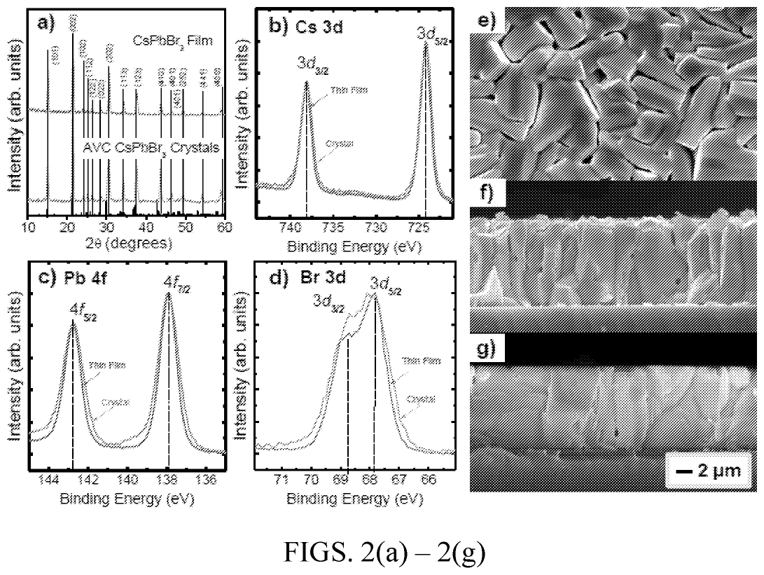

In the CSS process the material transforms from solid phase to vapor phase without going through the liquid phase. In comparison, in Bridgman process the melt is crystallized and hence the required temperature is much higher than that of CSS. Further, the time required for Bridgman crystal growth is much higher than that of CSS. Thus, the CSS process is not only economical but also permits large area applications. Table 2 in Example 1 below demonstrates a comparison between the material parameters of Bridgman crystals and the thin films developed by CSS. The data in FIG. 2 shows that the material parameters of the CSS deposited thin films are comparable with those of the Bridgman single crystal data.

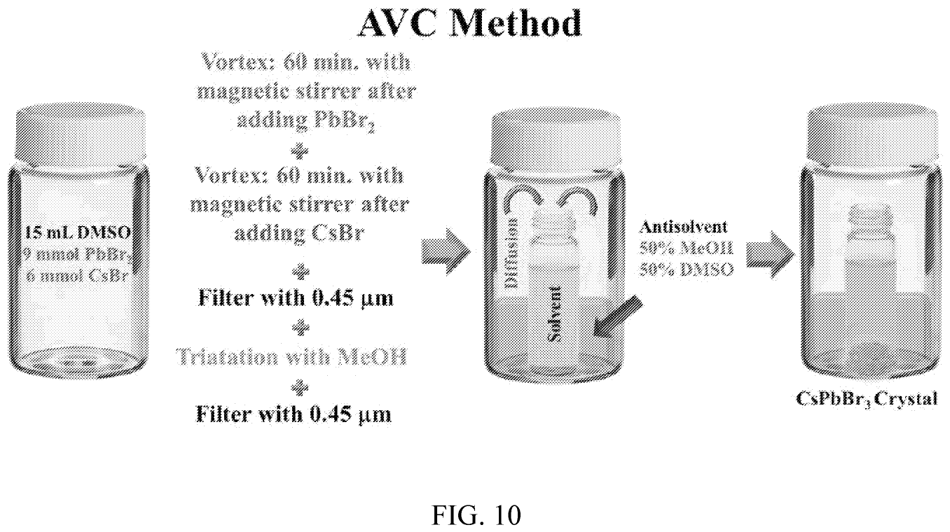

FIG. 1(a) shows a schematic view of an antisolvent vapor crystallization (AVC) approach for growth of crystals (e.g., CsPbBr₃ crystals) that can be used as a source material for a CSS process. Though FIG. 1(a) refers to CsPbBr₃ crystals and a temperature of 25° C., these are for exemplary purposes only. In addition, FIG. 10 shows a more detailed schematic view of the AVC method for preparation of crystals (e.g., CsPbBr₃ crystals). Though FIG. 10 refers to certain materials and solvents, these are for exemplary purposes only and should not be construed as limiting.

Referring to FIGS. 1(a) and 10, crystals (e.g., CsPbBr₃) to be used for the source material can be grown using an AVC method (see also, e.g., [8], which is hereby incorporated by reference herein in its entirety). As a first step, starting materials containing the elements of the crystals (e.g., PbBr₂ and CsBr for CsPbBr₃ crystals) can be dissolved in a solvent (e.g., dimethyl sulfoxide (DMSO)) with continuous stirring for a predetermined amount of time (e.g., 1 hour (h)) at a predetermined temperature (e.g., room temperature). Then, the solution can be filtered, and the resulting clear solution can be titrated with another solvent (e.g., methanol (MeOH)). The titrated solution can be filtered again to obtain the precursor solution for crystal growth. In a second step, the precursor solution can be placed in a first container (e.g., a beaker) and covered with filter paper. The first container can then be placed in a larger second container (e.g., another beaker) containing an antisolvent (e.g., 50% MeOH and 50% DMSO) and sealed. The precursor solution and AVC bath can be placed in a furnace maintained at set temperature (e.g., in a range of 25° C. to 35° C.). Vapor of the precursor solution (e.g., MeOH vapor) can penetrate through the filter paper to promote nucleation and crystal growth. The crystals can be washed with a third solvent (e.g., dimethylformamide (DMF) solution) at a predetermined temperature (e.g., room temperature) and stored (e.g., in a sealed container such as a glove box).

The single crystal growth AVC method produces only tiny crystals, in comparison to the large ingots obtained from high temperature processes such as a Bridgman technique. The AVC method induces crystal formation in solution at temperatures close to ambient. The cost involved in this synthesis is the same as any chemical process to produce the raw material. For example, the only necessary accessories can be a few beakers, a stirrer, and an oven that can maintain a relatively low elevated temperature (e.g., 30° C.). This approach does not introduce additional cost in precursor synthesis and instead provides good quality material at low cost. The only restraint in this approach is that approximately three days are needed to get reasonably good yield as opposed to instant precipitation of the material. However, the phase-purity of the tiny crystals is superior to that of a precipitate.

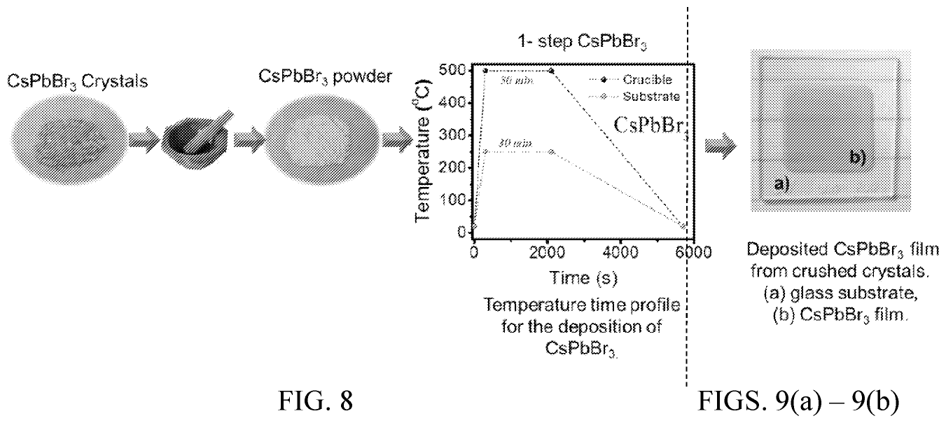

FIG. 8 shows a schematic view of precursor powder preparation from crystals. Though FIG. 8 refers to CsPbBr₃ crystals and CsPbBr₃ powder, these are for exemplary purposes only. Referring to FIG. 8, the crystals (e.g., crystals prepared by an AVC method) can be ground (e.g., using a mortar and pestle or similar process) to produce a powder. The powder can be used as the source material for the CSS process to produce a film of the same composition as the source material. FIG. 8 also shows a plot of temperature (in ° C.) versus time (in seconds (s)) for the deposition of a CsPbBr₃ thin film from CsPbBr₃ powder. The upper curve is for the crucible, and the lower curve is for the substrate. At time=2000 s, the heaters were switched off and the reactor was left to cool until the temperature reached below 50° C. The thickness of the film after the deposition time of 1800 s was 5 μm. FIG. 9(b) shows an image of the deposited CsPbBr₃ thin film, and FIG. 9(b) shows an image of the glass substrate used for the deposition.

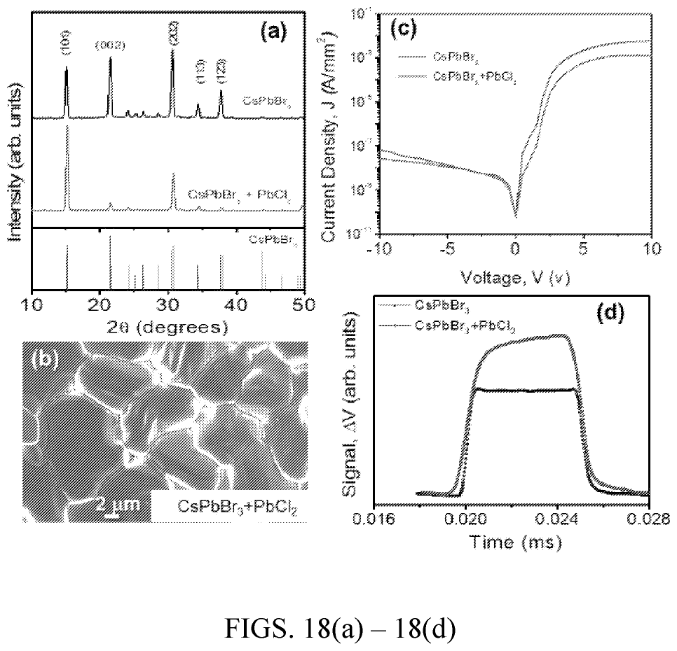

The thickness of the deposited film can be controlled by varying the deposition time. Longer deposition times (i.e., running the CSS process for longer times) results in thicker deposited films. In some embodiments, after deposition a polishing process (e.g., mechanical polishing) can be performed to reduce surface roughness of the deposited film, and/or a post-deposition anneal (e.g., at a temperature of about 450° C. for about 30 minutes) can be performed. In certain embodiments, the deposited film can be subjected to a chemical or thermal treatment (e.g., a thermal treatment in a vapor of a chemical, such as PbCl₂ vapor); the chemical/thermal treatment can be performed before or after polishing (if polishing is done) and before or after post-deposition annealing (if post-deposition annealing is done). FIGS. 18(a)-18(d) show results for a diode with a CsPbBr₃ thin film and with a PbCl₂-treated CsPbBr₃ thin film.

FIG. 1(c) shows a schematic view of a diode having a thin film (labeled in FIG. 1(c) as CsPbBr₃) produced by a CSS process according to an embodiment of the subject invention. The cathode (+) and anode (−) are labeled, as are the electrical contacts (indium tin oxide (ITO) and gold). A semiconductor material can be used (e.g., Ga₂O₃, such as n-type Ga₂O₃). Though FIG. 1(c) refers to the diode being a CsPbBr₃ diode, the thin film being CsPbBr₃, the electrical contacts being ITO and gold, and the semiconductor being Ga₂O₃, these are for exemplary purposes only.

No related art systems or methods exist for neutron detection using CsPbBr₃-based diodes or the deposition of CsPbBr₃ (or related) films using a CSS process. The photon attenuation coefficient of CsPbBr₃ is linear and comparable to that of CZT for energies up to 1000 kilo-eV (keV). The interaction of CsPbBr₃ two-dimensional (2D) nanosheets with ionizing radiation shows scintillation performance comparable to some commercial crystals. The observed luminosity of about 21,000 photons per mega-eV (photons/MeV) is comparable to that of commercial Cs₂LiYCl₆:Ce (CLYC) crystals, but the luminescence decay time of less than 15 nanoseconds (ns) is much shorter than that of NaI:Tl (about 200 ns), CLYC (greater than 50 ns), and LaBr₃(Ce) (greater than 16 ns). Although single crystals of CsPbBr₃ can provide improved optoelectronic properties due to the intrinsic phase purity and crystal quality, the high cost of the single crystal approach renders this a poor option for portable and large area applications. Hence, films (e.g., films with a thickness of at least 5 μm, or thin films with a thickness of less than 50 μm) of CsPbBr₃ and related materials are a good alternative option for neutron detection.

Solution processing for thin-film deposition (e.g., chemical vapor deposition (CVD), vacuum evaporation, or hybrid vacuum-solution process) is flexible, but the stability and electronic properties of the resulting materials can be compromised by impurities and solvents incorporated from the precursor solution. Physical vapor deposition (PVD) methods eliminate solvents and yield higher quality materials, but precursor utilization is low and not practical for depositing thin films with sufficient thickness for efficient high energy electromagnetic radiation and neutron sensing.

Embodiments of the subject invention address the above issues of solution processing and PVD methods by using a CSS process that is solution-free, simple, scalable, inexpensive, and gives a high growth rate for depositing high quality films (e.g., CsPbBr₃). CsPbBr₃ melts congruently at about 570° C., sublimation from pure CsPbBr₃ powder or crystals can produce near stoichiometric films. The fact that CSS is a near-thermal-equilibrium deposition process results in films with reduced defects, large-grain films with less grain boundaries and carrier scattering, high material utilization, and high growth rates.

Embodiments of the subject invention provide CSS processes for the deposition of films (e.g., perovskite films) with a thickness in the range of from 100 nanometers (nm) to 100 μm. Deposition can be performed using crystals of the film material as source material to obtain films with the same compositional and stoichiometric features as the source material and grain size comparable to film thickness (i.e., the deposited film can have a grain size that is about equal to the thickness of the film). For example, perovskites can be used as source material, obtaining inorganic perovskite films with the same compositional and stoichiometric features as the perovskite source material, with grain size comparable to the film thickness. Single crystal precursor can be ground into powder and used to achieve high quality films (e.g., perovskite films) that can be used for, e.g., radiation detection. Films of many different compositions can be deposited using different source materials, and halide composition can be tuned. Embodiments can provide dynamic film composition control by modifying the precursor materials and/or concentrations. Embodiments provide for fast growth rate, allowing for thick film deposition with large grains, as well as solution-free film deposition and the ability to sublimate ternary and quaternary compounds.

A greater understanding of the embodiments of the subject invention and of their many advantages may be had from the following examples, given by way of illustration. The following examples are illustrative of some of the methods, applications, embodiments, and variants of the present invention. They are, of course, not to be considered as limiting the invention. Numerous changes and modifications can be made with respect to the invention.

### Example 1

CsPbBr₃ films with thicknesses of about 8 μm were deposited by a CSS process as illustrated in FIGS. 1(b) and 21(a) from CsPbBr₃ crystallites grown using the AVC method as illustrated in FIGS. 1(a) and 10. The deposition of the CsPbBr₃ films was carried out under vacuum (70 milliTorr (mTorr)). The source (container) and substrate temperatures in the CSS process were at 500° C. and 250° C., respectively. The temperature profiles for the source (Tsou) and substrate (Tsub) in the CSS reactor are shown in FIG. 8 (plot at the right side). The thickness of the film was controlled by varying the deposition time. Films were optionally polished and/or subjected to a post-deposition anneal at 450° C. for 30 minutes.

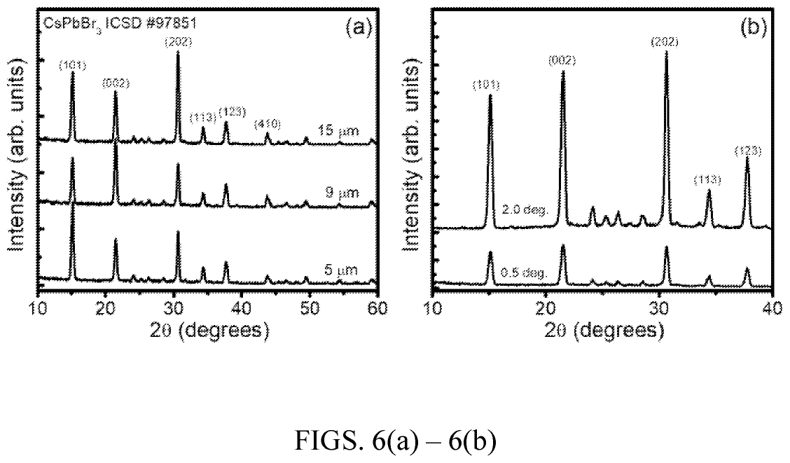

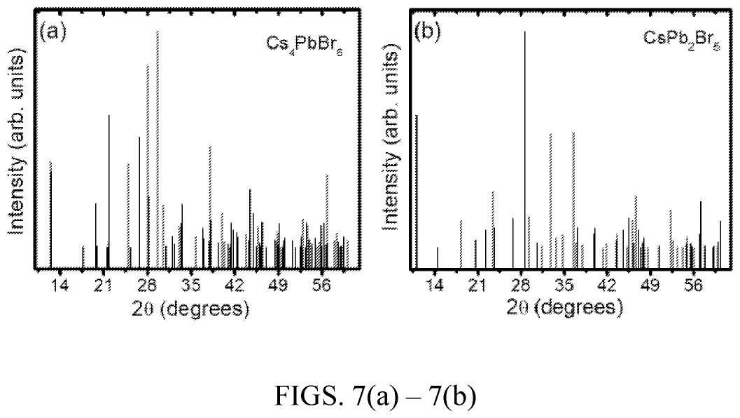

FIG. 2(a) shows the X-ray diffraction (XRD) patterns of the CsPbBr₃ precursor crystals and the resulting CsPbBr₃ film. The CSS-deposited CsPbBr₃ films have the same crystallographic nature and phase purity as the precursor crystals. High incident angle (2 degrees) XRD analyses confirmed the phase-purity in the bulk of the CSS deposited CsPbBr₃ films with the orthorhombic perovskite structure, as seen in FIGS. 6(a) and 6(b). No diffraction peaks for polymorphs Cs₄PbBr₆ or CsPb₂Br₅ were observed, further demonstrating the phase purity of the deposited CsPbBr₃ films (see also FIGS. 7(a), 7(b), and [34]). The crystallite size of the as-deposited CsPbBr₃ was in the range of about 245 nm with lattice constants a=8.205 Angstroms (Å), b=11.694 Å, and c=8.268 Å, consistent with the orthorhombic CsPbBr₃ phase (see [19). Identical lattice constants for films and the crystalline precursor were calculated and are shown in Table 1. Referring to Table 1, the calculations are based on (002), (202), and (123) planes (ICSD #97851). A comparison of electrical properties between a CsPbBr₃ crystal grown by the Bridgman method and a CsPbBr₃ thin film deposited by CSS according to an embodiment of the subject invention (listed as “our study”) is shown in Table 2.

TABLE 1
Lattice constants of single crystal
source material and deposited films

| | a (Å) | b (Å) | c (Å) |
|---|---|---|---|
| Crystal | 8.2153 | 11.6279 | 8.2988 |
| Film (5 μm) | 8.2069 | 11.6336 | 8.2668 |
| Film (9 μm) | 8.2051 | 11.6946 | 8.2680 |
| Film (15 μm) | 8.2101 | 11.5386 | 8.2818 |

The X-ray photoelectron spectroscopy (XPS) spectra of the CsPbBr₃ film and crystals are shown in FIGS. 2(b)-2(d). The binding energies for the Cs 3d, Pb 4f, and Br 3d regions are consistent with CsPbBr₃ (see also [35]). Further, the binding energies match for both the source crystals and the thin films, indicating that the CsPbBr₃ stoichiometry/composition and crystalline structure of the crystals are maintained during the CSS deposition process.

TABLE 2
Comparison of electrical parameters of thin film deposited
by CSS and single crystal grown by Bridgman method

| | | | CsPbBr₃ | |
|---|---|---|---|---|
| | CsPbBr₃ | | CSS deposited | |
| Parameter | Bridgman Crystal | | film (our study) | |
| Carrier | 1 × 10⁹ | cm^{-3 [3]} | 5 × 10⁹ | cm⁻³ |
| concentration | | | | |
| Mobility | 11.61 | cm² (V s)^{-1 [4]} | 0.013 | cm² (V s)⁻¹ |
| Resistivity | 3.40 × 10¹¹ | Ω-cm ^{[5]} | 1 x 10¹¹ | Ω-cm |
| Work function | 4.22 ^{[4]} | | 4.8 | eV |
| Lifetime | 1.2 and 8.65 ns ^{[4, 6-7]} | | 1.37 and 4.28 ns | |
| Rise/Decay time | 69/261 | μs ^{[7]} | 190/450 | μs |

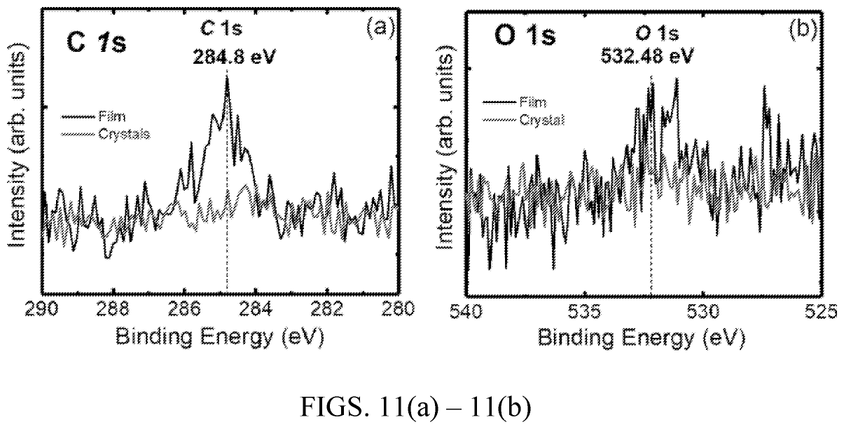

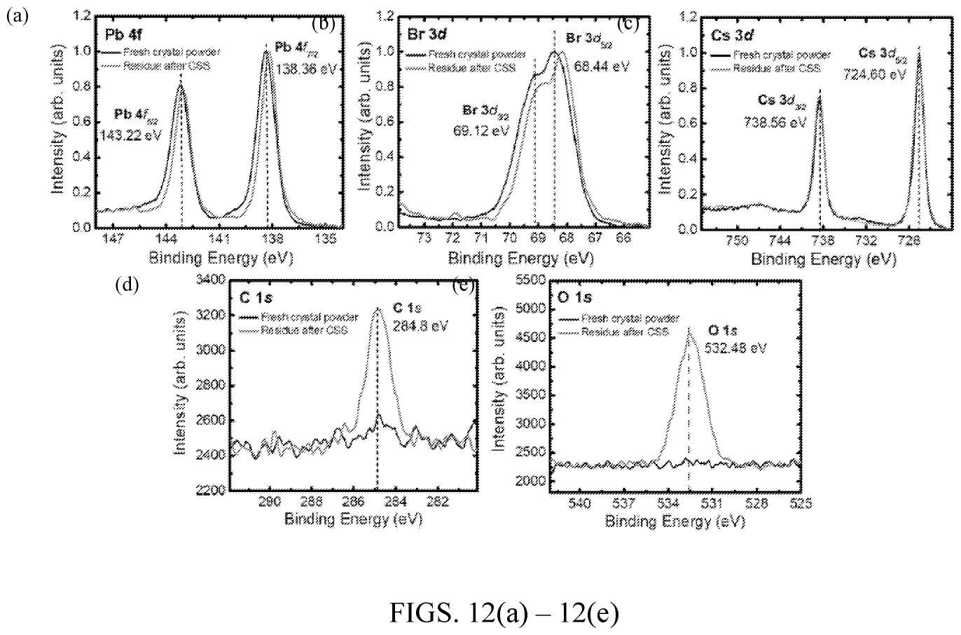

In order to investigate the purity (contamination) of the material after exposing to high temperature, NIPS was performed on the residue powder in the crucible. The NIPS results for C 1s and O 1s regions for the CsPbBr₃ crystal before and after the sublimation as well as for the film are shown in FIGS. 11(a) and 11(b). The XPS shown in FIGS. 12(a)-12(e) corresponds to the freshly crushed crystal and the residue powder in the crucible after the CSS process. The data show an increase in carbon and oxygen contaminants. These results indicate that the reuse of the residue powder can result in films with lower material quality, which can potentially affect device performance. For this reason, it is advantageous to use freshly crushed crystals for film deposition.

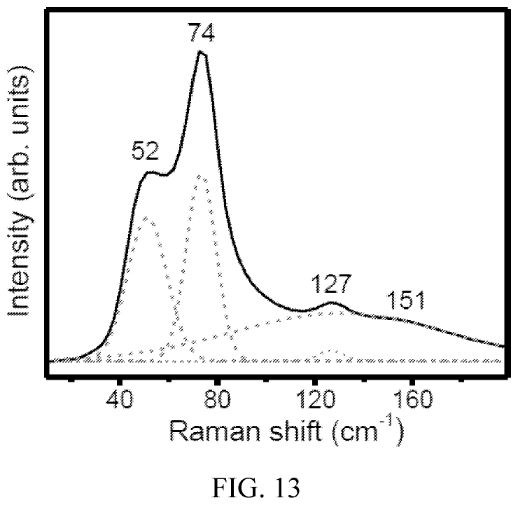

The CsPbBr₃ structure was also confirmed by Raman spectroscopy analysis. Referring to FIG. 13, the Raman results further demonstrate an orthorhombic phase with bands at 52 cm⁻¹ and 74 cm⁻¹ assigned to vibrational modes of the [PbBr₆]⁴⁻ octahedron and the bands at 127 cm⁻¹ and 151 cm⁻¹ to Cs⁺ ion vibrations (see also [36], [37]). The broad band at 151 cm⁻¹ is due to fluorescence effects. The Pb—Br rocking modes in the [PbBr₆]⁴⁻ octahedron for Cs₄PbBr₆ have two intense bands at about 86 cm⁻¹ and about 127 cm⁻¹ (see also [18], [38]; however, the absence of the 86 cm⁻¹ band and the weak nature of the band at 127 cm⁻¹ confirms that no Cs₄PbBr₆ is present. The weak nature of the 127 cm⁻¹ band is characteristic of CsPbBr₃ (see also [18], [37], [38]).

Surface morphology of the as-deposited films (FIG. 2e), as evaluated by scanning electron microscopy (SEM), shows grains with average size of about 2.5 μm× about 6.5 μm with dense columnar growth (see FIG. 2f). Recrystallization is evident after annealing at 450° C. for 30 min. This annealing was introduced to further increase the grain size and density of the films (see FIG. 2g). The grain size and columnar growth of the CSS-deposited CsPbBr₃ is in sharp contrast with the smaller grains observed in films deposited by solution process or physical methods such as CVD and co-evaporation (see also [28], [39]).

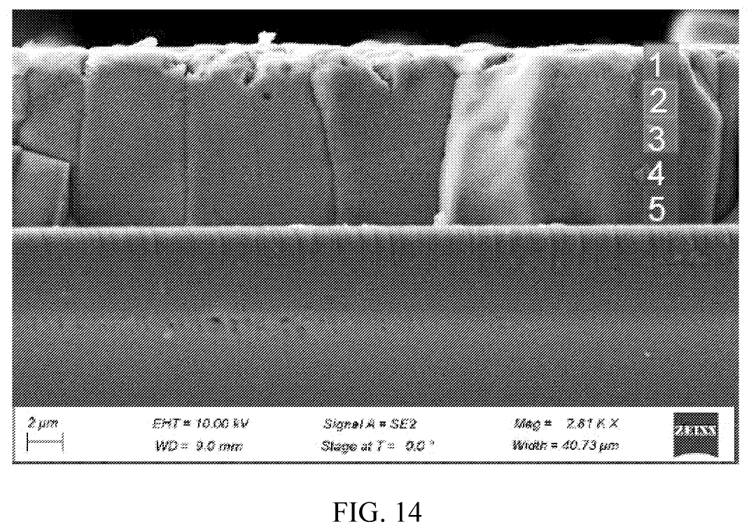

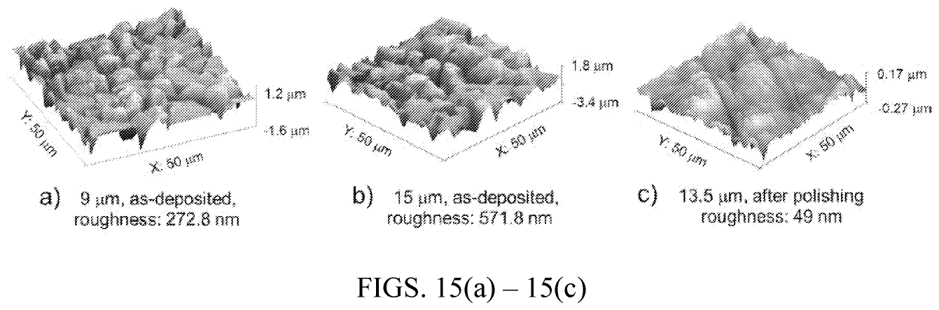

Energy dispersive X-ray spectroscopy (EDXS) analysis was performed across the film cross section at five points, as shown in FIG. 14 and Table 3, to examine any possible variation in stoichiometry. The composition was maintained constant (or essentially constant) throughout the film thickness, except a slight variation near the substrate where the initial film growth happens. Though this difference is small, it can make the interface region distinct from the bulk. The surface roughness of the CsPbBr₃ film could result in discontinuities at the interface due to poor coverage of the contact films. To avoid this, a polishing process to reduce the surface roughness can be performed. Such a polishing process was introduced, reducing the roughness from about 270 nm to less than 50 nm (see FIGS. 15(a)-15(c)).

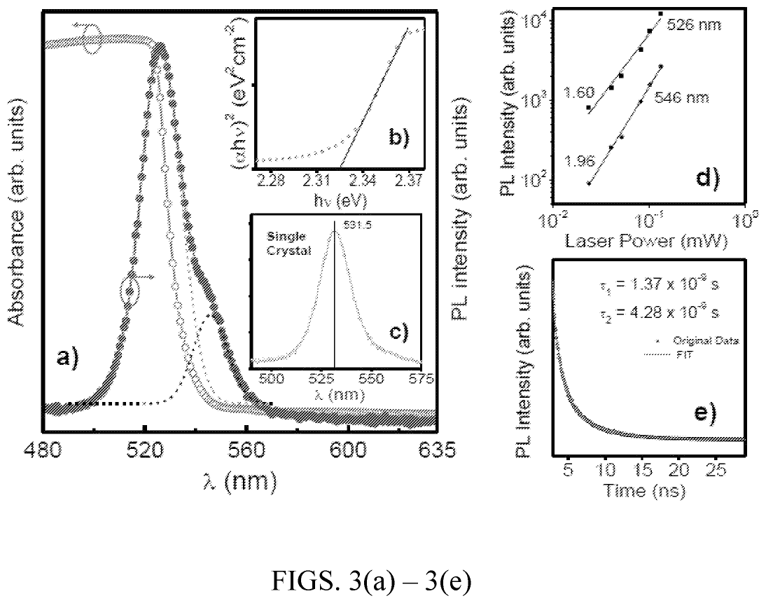

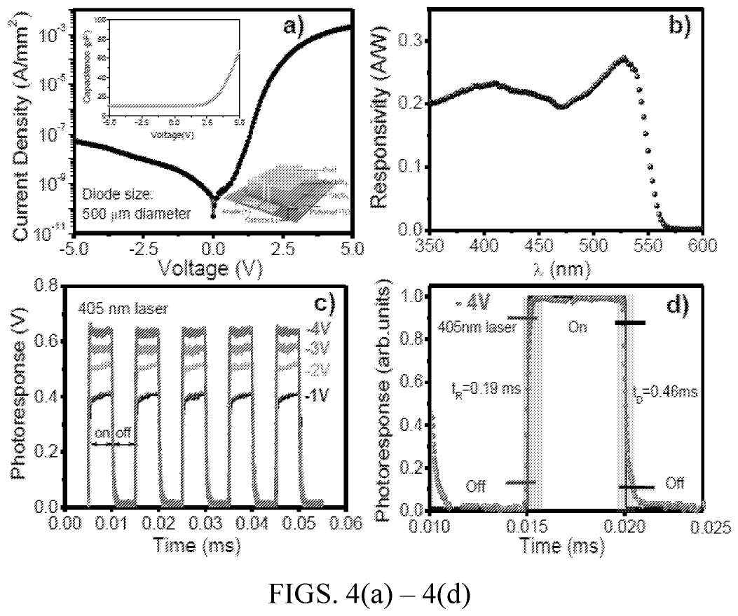

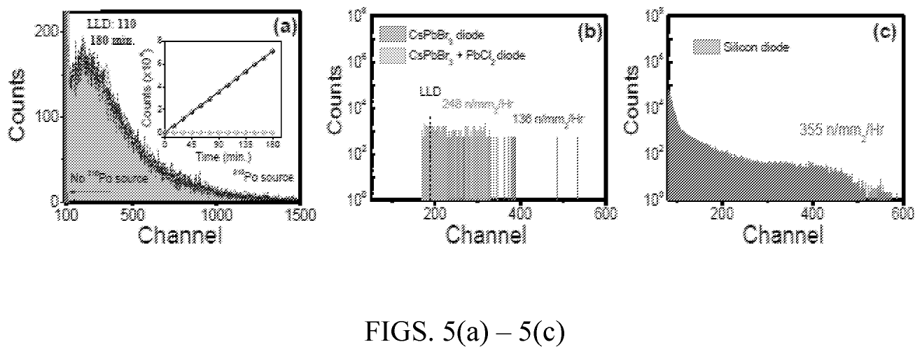

The photoluminescence (PL) spectra of the films reveal a strong emission centered at 526 nm with a weak shoulder at 546 nm (see FIG. 3a). The band gap of the thin-film material was estimated to be 2.32 eV from the Tauc plot shown in FIG. 3b. The weak band at 546 nm in the PL spectra of the thin film could be associated with several phenomena including photon recycling, structural differences between surface and bulk leading to slightly different band gaps, bound excitons, and/or defects due to grain size inhomogeneity or traces of precursor (see also [40], [41], [42], [14], [43]). Based on the SEM and XRD analysis (0.5 and 2.0 degree grazing angles) grain size inhomogeneity and traces of precursor can be ruled out. Photon recycling can happen in translucent materials, and the red-shifted PL band can be observed along with the original PL emission when the signal is captured from a wide area.

TABLE 3
Results of single-point EDXS over the cross-section of
the CsPbBr3 film (the five data collection locations,
labeled as 1-5 respectively, are shown in FIG. 14)

| | | | | |
|---|---|---|---|---|
| Location on | Depth | | | |
| the cross- | from | Cs | Pb | Br |
| section | surface | (%) | (%) | (%) |

| | | | | | |
|---|---|---|---|---|---|
| 1 | 0-2 | μm | 20.10 | 18.49 | 61.41 |
| 2 | 2-4 | μm | 20.16 | 18.47 | 61.37 |
| 3 | 4-6 | μm | 20.33 | 19.03 | 60.63 |
| 4 | 6-8 | μm | 21.22 | 18.41 | 60.37 |
| 5 | 8-10 | μm | 19.94 | 20.68 | 59.38 |

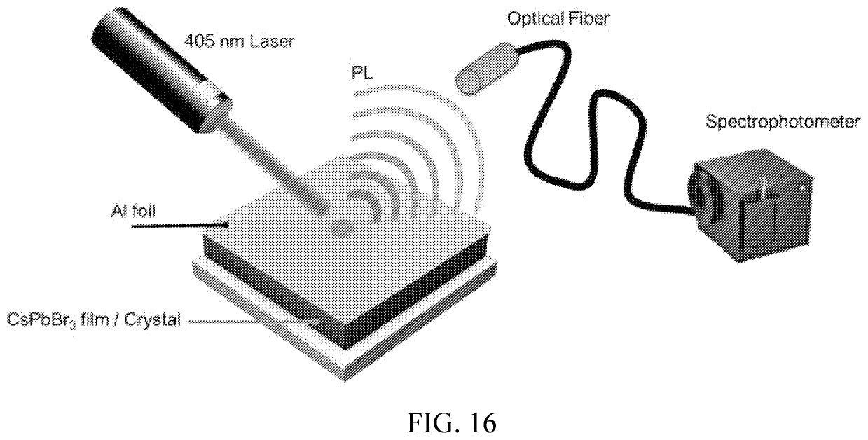

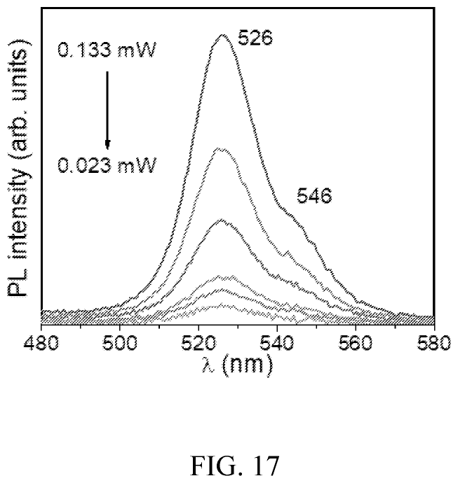

FIG. 16 shows a schematic view of an experimental arrangement used for obtaining and recording PL spectra from thin films and crystals. In order to minimize the interference of re-emitted photons, the PL signal was recorded through a pin-hole (˜400 μ), as shown in FIG. 16. Absence of a shoulder band in the PL spectrum of the CsPbBr₃ precursor crystal (see FIG. 3c) rules out the possibility of interference from recycled PL. The full width at half maximum of both PL bands of the film is identical with that of the single crystals (about 19 nm), indicating that no additional near-edge defect levels exist in the film. FIG. 17 shows a plot of PL intensity (a.u.) versus wavelength (in nm) for the CsPbBr₃ thin film, recorded at different incident laser powers (from 0.133 mW to 0.023 mW).

In order to further explore the origin of the PL bands in the CsPbBr₃ film, the area under the curve of the PL bands (526 nm and 546 nm) after deconvolution was plotted as a function of incident laser power (see FIG. 3d). Both bands showed a power law dependence and exponential coefficients of 1.6 and 1.96 for the 526 nm and 546 nm emissions, respectively. When excited with laser energy (hv) greater than the band gap, an exponent value between 1 and 2 indicates free- or bound-exciton emissions (see also [14], [44]). Therefore, the PL band at 526 nm, which coincides with the band gap, is assigned to free-exciton emission and the 546 nm band to bound-excitons (see also [20]). The time-resolved photoluminescence (TRPL) of the CsPbBr₃ film showed two decay processes with lifetimes of 1.37 ns and 4.28 ns, consistent with decay times for CsPbBr₃ single crystals and quantum dots (3.5 ns and 11.4 ns) (see FIG. 3e, [18], and [15]).

### Example 2

The CsPbBr₃ single crystals used for the thin films of Example 1 were grown using the AVC method described herein. As a first step 9 millimoles (mmol) of PbBr₂ and 6 mmol of CsBr were dissolved in 15 milliliters (mL) of DMSO with continuous stirring for 1 h at room temperature. After that, the solution was filtered using a 45 m-sized filter. The resulting clear solution was titrated with MeOH until a slight orange color appeared. Then, the solution was filtered again to obtain the precursor solution for crystal growth.

In the second step approximately 20 mL of the precursor solution was disposed in a beaker and covered with filter paper. The beaker with precursor was placed in a larger beaker containing 30 mL of antisolvent (50% MeOH and 50% DMSO) and sealed. The precursor and the AVC bath were placed in a furnace maintained at temperature in the range 25° C. to 35° C. MeOH vapor penetrating through the filter paper promoted the nucleation and crystal growth over a period of three days (see FIG. 10). The crystals were washed with DMF solution at room temperature and stored in a glove box.

The single crystals were pulverized with an agitate mortar and pestle. About 100 milligrams (mg) of the powder was used in each deposition for obtaining films with thickness of about 8-9 μm.

### Example 3

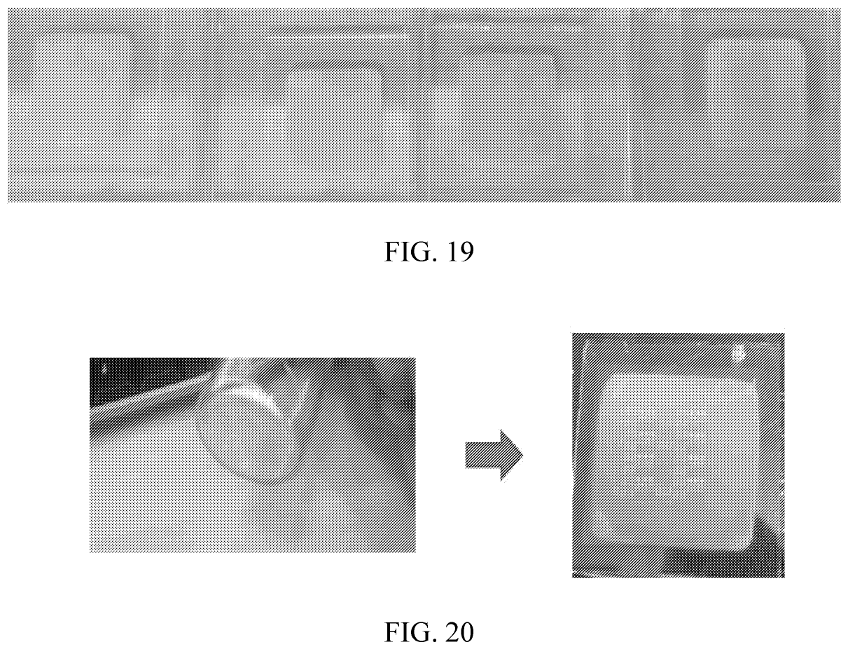

The same processes of Examples 1 and 2 were used, but with different materials. Mixed halides were obtained by changing precursor concentrations (i.e., CsBr/CsCl and PbCl₂/PbBr₂). Deposited mixed halides films are shown in FIG. 19. Film deposition conditions were kept the same as shown in the plot in FIG. 8.

CsPbCl₃ were grown from pure CsPbCl₃ crystals prepared by the AVC method. FIG. 20 shows images of the CsPbCl₃ crystals prepared by an AVC method (left) and the resulting thin film on a glass substrate after the CSS process (right). The film sublimation was carried at 350° C. crucible temperature and 200° C. substrate temperature. The resulting film showed single-phase CsPbCl₃ perovskite with a final thickness of about 7 μm.

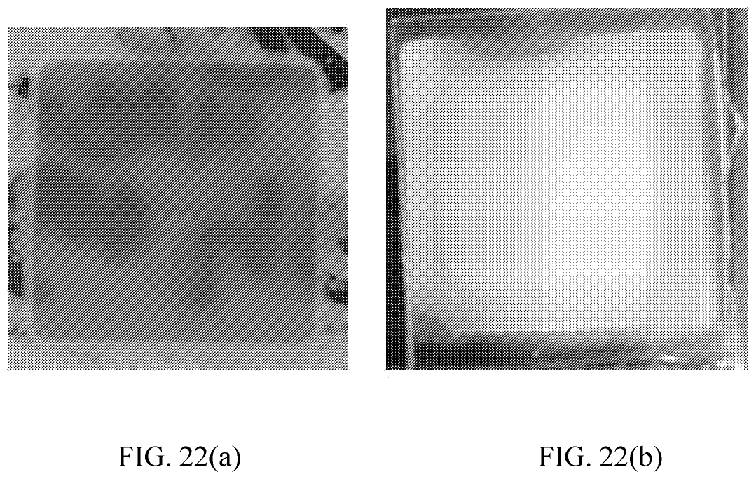

A two-step deposition was carried out by sequential deposition of a lead bromide (PbBr₂) film and the deposition of an organic methylammonium bromide (MABr), iodide (MAI), or chloride (MACl) film on top using the CSS conditions shown in FIGS. 21(b)-21(d). FIGS. 21(b)-21(d) refer to MABr, but the same conditions were used for MAI and MACl. PbBr₂ (or lead iodide for MAI or lead chloride for MACl) was sublimated onto the substrate by heating the crucible at 400° C. and maintaining the substrate temperature at 240° C. Immediately after subliming the PbBr₂, the MABr precursor is sublimed, producing a partially converted MABr film in situ. FIG. 22(a) shows an image of the MAPbBr₃ deposited by the CSS process, and FIG. 22(b) shows an image of the MAPbCl₃ deposited by the CSS process.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein (including those in the “References” section) are incorporated by reference in their entirety, including all figures and tables, to the extent they are not inconsistent with the explicit teachings of this specification.

1. A method for depositing a film on a substrate, the method comprising:
providing a source material on a first heater, the source material comprising single crystals;
providing the substrate on a second heater, the substrate being disposed a first distance from the source material, the first distance being less than 10 millimeters (mm);
performing a close space sublimation (CSS) process to deposit the film of the source material on the substrate by simultaneously heating the source material with the first heater to a first temperature and heating the substrate with the second heater to a second temperature,
wherein the film has the same stoichiometry as the source material.

2. The method according to claim 1, wherein the first distance is no more than 3 mm.

3-4. (canceled)

5. The method according to claim 1, wherein the source material is a perovskite material and the film is a perovskite film.

6. The method according to claim 1, wherein the source material is CsPbBr₃ and the film is a CsPbBr₃ film.

7. The method according to claim 1, wherein the film has a thickness in a range of from 100 nanometers (nm) to 100 micrometers (μm).

8-9. (canceled)

10. The method according to claim 1, wherein the source material comprises a powder of the single crystals ground up.

11. The method according to claim 1, wherein the source material is provided on the first heater in a container.

12. (canceled)

13. The method according to claim 11, wherein the container is in direct physical contact with the first heater.

14. The method according to claim 1, wherein the substrate is glass.

15. The method according to claim 1, wherein the substrate is in direct physical contact with the second heater.

16. (canceled)

17. The method according to claim 1, wherein the first temperature is higher than the second temperature.

18. The method according to claim 1, wherein the first temperature is at least twice the second temperature.

19. (canceled)

20. The method according to claim 1, wherein the first temperature and the second temperature are controlled by a first thermocouple and a second thermocouple, respectively.

21. The method according to claim 1, further comprising, after performing the CSS process:
allowing the substrate to cool to room temperature; and
performing a post-deposition annealing on the film by heating it to a third temperature for a predetermined period of time,
wherein the third temperature is at least 450° C. and the predetermined period of time is at least 1 hour.

22. (canceled)

23. The method according to claim 1, wherein the film has the same composition as the source material.

24. The method according to claim 1, wherein a grain size of the film is the same as a thickness of the film.

25. The method according to claim 1, comprising preparing the source material using an antisolvent vapor crystallization (AVC) method.

26. A film deposited by the method according to claim 1.

27. The film according to claim 26, wherein the film is a perovskite film.

28. The film according to claim 26, wherein the film is a CsPbBr₃ film.
